(19) United States
(12) Patent Application Publication
(10) Pub. No.: US 2004/0124006 A1
(43) Pub. Date: Jul. 1, 2004

(54) Built up lands

(76) Inventors: Tom E. Pearson, Beaverton, OR (US); Raiyo Aspandiar, Portland, OR (US); Christopher D. Combs, Portland, OR (US); George Arrigotti, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/334,734

(22) Filed: Dec. 31, 2002

(51) Int. Cl. H05K 1/09

(52) U.S. Cl. 174/257

(57) ABSTRACT

A substrate of a component manufactured for surface mounting on a circuit board, comprising a substrate surface, a non-conductive mask layer on the substrate surface facing the circuit board, and a conductive contact land on the substrate surface which is exposed by an aperture provided in the mask layer and of a thickness sufficient to ensure that a contact surface of the land is at least level with, or protrudes beyond, the plane of the mask layer immediately surrounding the aperture.

### BACKGROUND

Integrated circuits (ICs) such as processors are manufactured in various types of packages. In one type of package, the IC is provided as a semiconductor die that is housed within the package and the package serves to encapsulate and protect the die and to provide connectivity between the IC implemented by the die and a device, such as a computer, within which the circuit is installed. One type of packaging system is a surface mount packaging system that uses a package with a substrate that includes, on its mounting surface, metal contacts or package lands that are internally connected to the integrated circuit within the package, or to other circuits within the package. These lands provide electrical power, ground, signal and data path connectivity to the IC, and other circuits, within the package.

The lands are then joined to solder balls or bumps or other conductive reflow elements such as conductive plastic balls by a reflow process. FIG. 1 depicts an embodiment of the prior art. In the figure, a simplified cross section of a package substrate 100, including a land, 140, is joined with a solder ball, 160. The package may then be mounted to a circuit board, such as a printed circuit board (PCB), with a set of PCB lands that correspond in number, layout and logical, signal, or electrical function to the lands on the package substrate, by a reflow process. The reflow process causes the reflow elements to form joints and electrical connections between the contacts on the package and the corresponding contacts on the PCB. This type of packaging or mounting is termed ball grid array (BGA) packaging or mounting.

The remainder of the surface of the package that mates with the PCB, other than the land surfaces, is covered with a layer of a material that is non-conductive, does not wet to reflowed solder or conductive plastic, and prevents moisture entry into the package. FIG. 1 at 120. This layer is called a solder mask, or a reflow mask. Typically, the package is a multi-layered article of manufacture manufactured by a process in which each successive layer is created in a manufacturing step. In a typical manufacturing process for such packages, the lands are fabricated within the package substrate, and then the solder mask layer is deposited. A mask process is used to selectively expose the lands for reflow and joining to solder balls (mask-defined lands). Because of the mask-defined nature of these lands, the process leaves the surfaces of the lands slightly within the surface of the solder mask layer, thus forming a collar or lip: an edge of solder mask that surrounds the land (FIG. 1 at 180); and a depression in the solder mask within which the land is exposed. FIG. 1 at 190.

When solder balls are joined to such lands, the solder flows into the depression created by the land and fills it, but because the solder does not wet the solder mask surface, the remainder of the solder ball extends outward away from the mask. See FIG. 1, generally. Thus, a neck of solder 190 is created in the depression within which the land is joined to the solder ball, starting at the contact surface of the land and ending at the edge or lip of the solder mask layer surrounding the land. This lip thus forms a corner that is in contact with the solder ball once it has solidified. FIG. 2 depicts a simplified version of a magnified cross section of the joint between a land and a solder ball in this situation. The figure depicts a land 200 defined by an aperture in the solder mask 280, joined to a solder ball 220. The layer 260 is called an intermetallic compound layer and is formed during the reflow soldering process. The neck of solder 240 formed by this arrangement can be clearly seen in FIG. 2, as can the corner or edge 290.

In typical use, a package of this type, bonded to a PCB by a surface mounting system as described above, is subject to mechanical and thermal stresses. Mechanical stresses may occur because of vibration from the environment within which the device that houses the PCB is used, or because of mobility. Thermal stresses may occur because of temperature increases and decreases that cause the package, package lands, solder balls, and PCB lands to expand and contract at potentially different rates owing, at least in part, to the different materials from which each is manufactured, causing stresses to occur.

As an effect of such stressing, solder balls are known to crack after a period of time due to solder fatigue, as depicted in FIG. 3 at 300. Such cracks are a problem because they can cause a failure of electrical connectivity between the package and the PCB, effectively causing the IC to malfunction or fail. Investigation into the causes of such cracking has revealed that such fatigue cracks often begin at the mask defined corner that is created by a manufacturing process as outlined above, because corners or edges are stress concentrators. FIG. 3 at 320. Thus, the corner created by the solder mask at the neck of the solder ball increases the stress to the solder ball at contact points along the edge of the mask surrounding the land. Fatigue cracks in solder balls due to repeated temperature cycling or mechanical vibration are often found to have begun at such a contact point.

This problem is currently managed by limiting the size of packages such that the thermo-mechanical stresses that build up in solder balls during temperature cycling are insufficient to form and propagate cracks under typical use conditions. Thermomechanical stress magnitudes depend on the size of the package. As more and more functions are incorporated into IC circuits, however, the number of contacts, and therefore the number of lands, required for packages will continue to increase, making size limitation difficult. Preload solutions that add downward preload stresses to the package may also mitigate the problem, reducing the stresses when the package experiences mechanical shocks and vibration. Such solutions are, however, expensive.

### BRIEF DESCRIPTION OF THE DRAWINGS

FIG. 1 depicts a cross section of a prior art substrate land joined to a solder ball.

FIG. 2 depicts a magnified view of a joint such as the one from FIG. 1

FIG. 3 depicts a crack propagating through a solder ball

FIG. 4 depicts a land-ball joint in an embodiment of the claimed subject matter

FIG. 5 depicts a magnified view of a joint such as the one from FIG. 4

FIG. 6 (6a-6g) depicts manufacturing process steps in one embodiment.

FIG. 7 depicts an assembly of a package and a circuit board in one embodiment

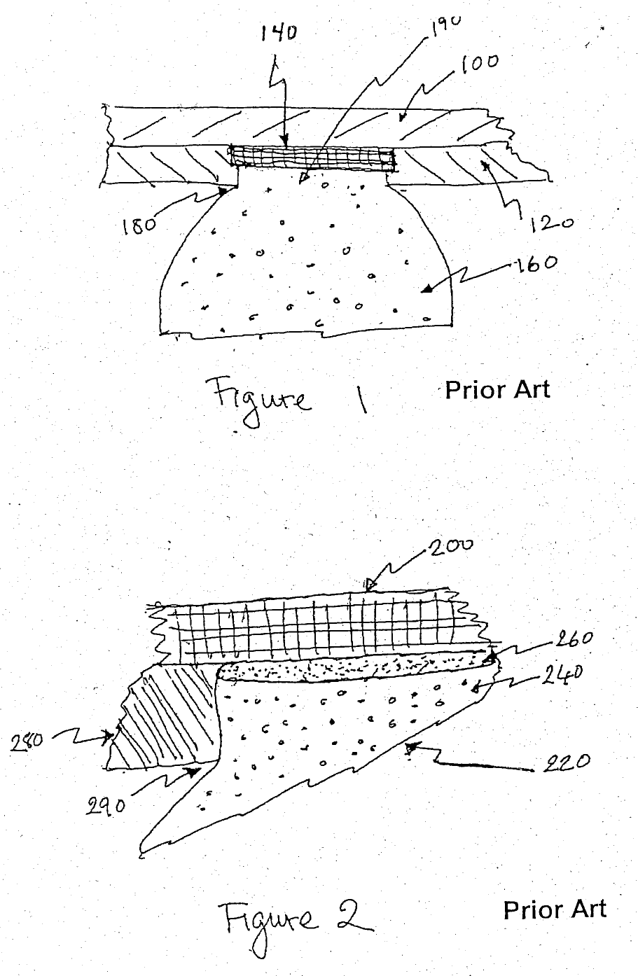

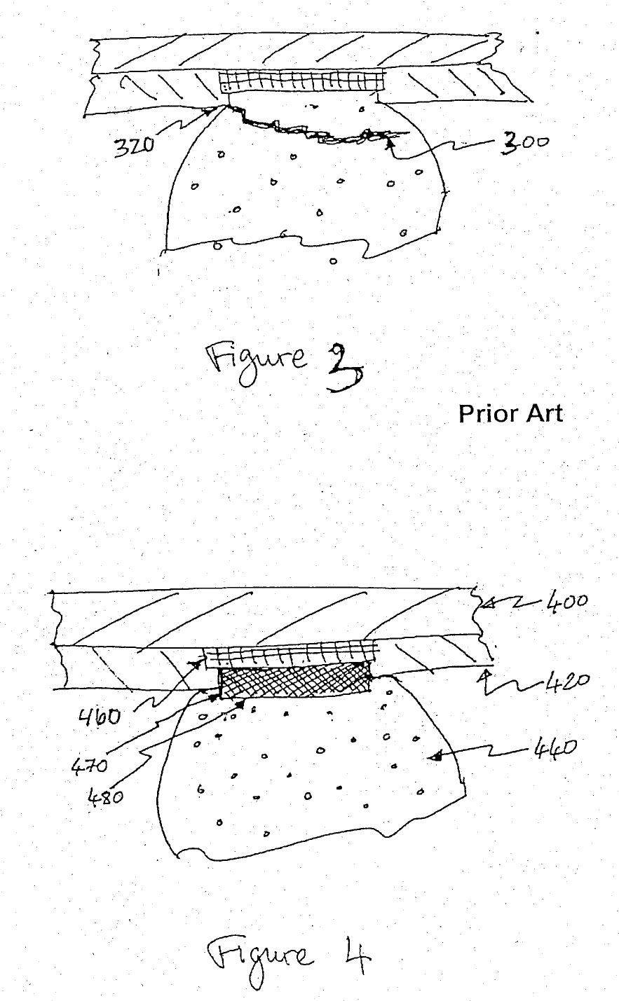

### DETAILED DESCRIPTION

Embodiments of the claimed subject matter generally relate to built up substrate lands in surface mount ball grid array package substrates fabricated so that they protrude out beyond the surface of the solder mask covering the substrate. A joint made with such a built up land by soldering a solder ball or bump or a similar reflow element then eliminates a solder neck and the mask defined sharp corner that are found in the prior art.

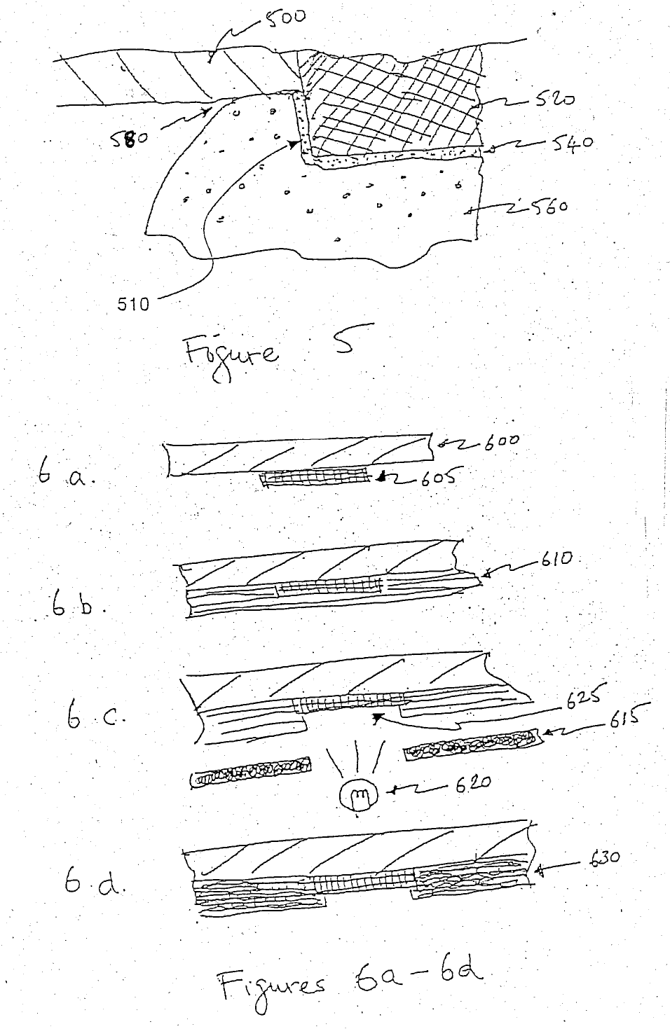

FIG. 4 depicts a substrate of a component in an embodiment of the claimed subject matter, joined with a solder ball. The substrate 400 is part of a package incorporating an IC and other circuits, connected to lands such as the one depicted at 460. The land may be constructed of a metal such as copper or of a copper alloy, among others. The lower surface of the substrate is covered with a layer of non-conducting solder mask 420 that prevents wetting by solder during a reflow process and acts as a moisture barrier. The land 460 is built up to a thickness such that the surface of the built up land extends at least up to if not beyond the surface of the solder mask immediately surrounding it, as depicted at 470, by copper plating 480. In the figure, the substrate is depicted in a joined state, where a solder ball 440 has been joined to the land by a reflow process.

FIG. 5 depicts a simplified and magnified view of the key aspects of the embodiment of FIG. 4. As may be seen in FIG. 5, the solder ball 560 forms a joint between a substrate and a land in this embodiment by wetting the entire contact surface including part of the side 510 of the built up land 520 during the reflow process, forming an intermetallic compound layer 540 along the entire contact surface. The solder ball does not wet or adhere to the solder mask 500 during reflow and therefore curves smoothly away from it at 580 without any intervening lips or edges impinging upon its surface.

The embodiment depicted in FIG. 4 and in FIG. 5 is one of many possible embodiments of the claimed subject matter. The specific choice of material for the land and the built up plating may differ, for example, the land may be plated on its surface with gold. The reflow component (solder ball) need not be present as in the figure, which depicts it for expository purposes. The reflow component may in other embodiments be a conductive plastic ball. The terms “solder ball” and “ball grid array” are used to generally refer to a class of technologies and the actual reflow elements may not necessarily be ball- or sphere-like. The figures are shown in cross section, and they do not limit the plan view shapes that may be used. For example, lands may be circular in plan, or assume another shape such as a rectangle; the reflow element may similarly be elongated or rectangular in a plan view of this joint in some embodiments.

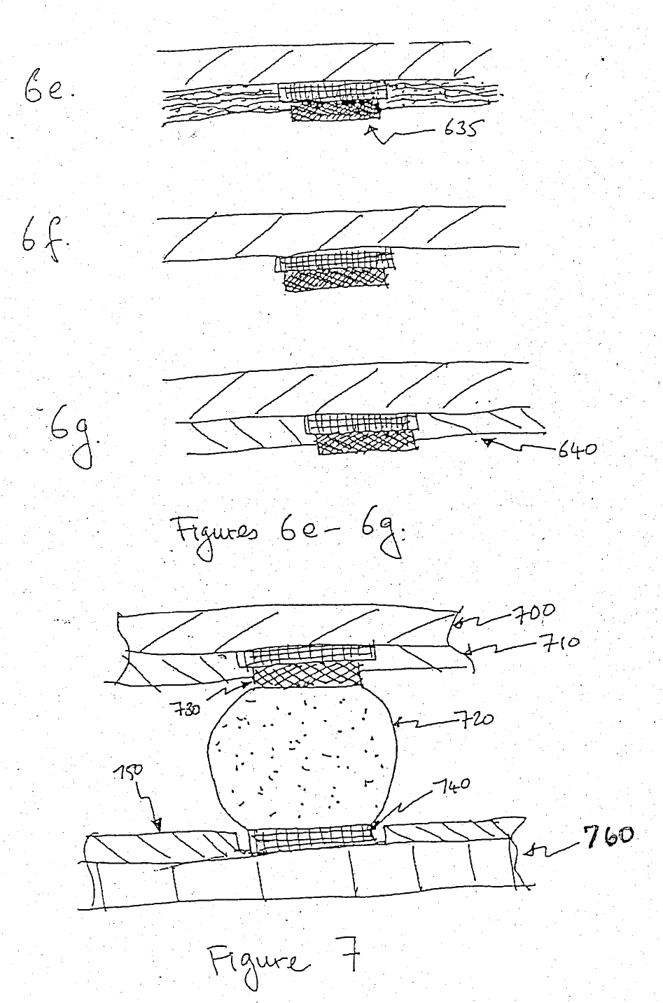

FIG. 6 depicts a manufacturing process at a high level. This process may be used in one embodiment of the claimed subject matter to fabricate a substrate as described above. In the initial state depicted in FIG. 6a, a cross section of a package substrate 600 with a fabricated land 605 is shown. In 6b, a photoresist layer 610 is deposited on the surface, covering the land. In FIG. 6c, the photoresist layer is exposed over the land using illumination 620 through a mask 615 using well-known fabrication techniques of photolithography, causing the land to become exposed. In FIG. 6d the remaining resist 630 is developed. FIG. 6e shows a panel-plating step that builds up the land 635 so that its surface protrudes above the surface of the resist. The resist is then removed (FIG. 6f) and a solder mask layer 640 applied and cured leaving the built up land as depicted in FIG. 6g. All of these steps may be accomplished using standard photolithographic process techniques.

FIG. 7 depicts an embodiment of the invention in an assembly including a printed circuit board 760 on which a package is mounted. The package substrate 700, built up land 730, solder mask layer 710 and solder ball 720 are substantially as depicted in FIG. 4. However, this figure also illustrates the joint between the solder ball and the PCB made to a PCB land 740, thus forming an electrical and mechanical connection between a surface mount package embodying the claimed subject matter and a circuit board.

Many modifications may be made to adapt the teachings of the description and the drawings to a particular situation without departing from their scope. Therefore, it is intended that the claimed subject matter not be limited to the various exemplary embodiments disclosed in the description and the drawings, but rather to all embodiments falling within the scope of the claims below.

What is claimed is:

1. A substrate of a component manufactured for surface mounting on a circuit board, comprising:
A substrate surface;
a non-conductive mask layer (mask layer), on the substrate surface facing the circuit board; and
a conductive contact land (land) on the substrate surface which is:
exposed by an aperture provided in the mask layer; and
of a thickness sufficient to ensure that a contact surface of the land is at least level with, or protrudes beyond, the plane of the mask layer immediately surrounding the aperture.

2. The substrate of claim 1 wherein the land forms an electrical connection and a joint with a reflow element when the reflow element and the land are heated above the reflow temperature of the reflow element, and wherein the distance by which the contact surface of the land protrudes beyond the plane of the mask layer immediately surrounding the aperture is such that the reflow element wets the interface between the side of the land and the outside surface of the mask layer, when the reflow element is heated above the reflow temperature of the reflow element.

3. The substrate of claim 2 further comprising the land joined with a conductive reflow element composed of a solder compound.

4. The substrate of claim 3 further comprising a land composed primarily of copper.

5. An assembly comprising:
A component with a substrate, surface mounted to a circuit board;
a non-conductive mask layer (mask layer), on the substrate surface facing the circuit board;
a first conductive contact land (first land) which is:
on the surface of the substrate facing the circuit board;
exposed by an aperture provided in the mask layer; and
of a thickness sufficient to ensure that the contact surface of the land is at least level with, or protrudes beyond, the plane of the mask layer immediately surrounding the aperture; and
a conductive reflow element joined with the first land and with a second conductive contact land (second land) on the surface of the circuit board.

6. The assembly of claim 5 wherein:
the first land forms an electrical connection and a joint with the reflow element when the reflow element and the land are heated above the reflow temperature of the reflow element; and
the distance by which the first land protrudes beyond the plane of the mask layer immediately surrounding the aperture is such that the reflow element wets the interface between the side of the first land and the outside surface of the mask layer, when it is above the reflow temperature.

7. The assembly of claim 6 wherein the reflow element is composed of a solder compound.

8. The assembly of claim 7 wherein the first land is composed primarily of copper.

9. A method of manufacture of a substrate of a component for surface mounting on a circuit board, comprising:
fabricating a conductive contact land (land) on the substrate;
fabricating a non-conductive mask layer on a surface of the substrate facing the circuit board and covering the land;
exposing the land by creating an aperture in the mask layer; and
extending the land to be at least level with, or to protrude beyond, the plane of the mask layer immediately surrounding the aperture.

10. The method of manufacture of claim 9 wherein fabricating a non-conductive mask layer further comprises fabricating a solder mask layer.

11. The method of manufacture of claim 10 wherein fabricating a land further comprises fabricating a land primarily composed of copper and capable of being joined by a reflow process to a solder ball.

12. The method of manufacture of claim 11 wherein extending the land further comprises panel plating the surface of the land.

13. A method of manufacture of an assembly by surface mounting a component on a circuit board, comprising:
fabricating a first conductive contact land (first land) on a substrate;
fabricating a non-conductive mask layer (mask layer) on a surface of the substrate facing the circuit board and covering the first land;
exposing the first land by creating an aperture in the mask layer;
extending the first land to be at least level with, or to protrude beyond, the plane of the mask layer immediately surrounding the aperture; and
joining a conductive reflow element with the first land and a second conductive contact land (second land) on the surface of the circuit board.

14. The method of manufacture of claim 13 wherein fabricating a non-conductive mask layer further comprises fabricating a solder mask layer.

15. The method of manufacture of claim 14 wherein fabricating a land further comprises fabricating a land primarily composed of copper and capable of being joined by a reflow process to a solder ball.

16. The method of manufacture of claim 15 wherein extending the first land further comprises panel plating the surface of the first land with copper.
